(19) United States
(12) Patent Application Publication
(10) Pub. No.: US 2025/0096066 A1
(43) Pub. Date: Mar. 20, 2025

(54) SEMICONDUCTOR PACKAGE

(71) Applicant: SAMSUNG ELECTRONICS CO., LTD., Suwon-si (KR)

(72) Inventors: Jing Cheng LIN, Suwon-si (KR); Youngkun JEE, Suwon-si (KR)

(73) Assignee: SAMSUNG ELECTRONICS CO., LTD., Suwon-si (KR)

(21) Appl. No.: 18/882,385

(22) Filed: Sep. 11, 2024

(30) Foreign Application Priority Data
Sep. 14, 2023 (KR) 10-2023-0122666

(51) Int. Cl. H01L 23/367; H01L 21/48; H01L 21/56; H01L 23/00; H01L 23/373; H01L 25/18; H05K 1/18; H10B 80/00

(52) U.S. Cl. CPC H01L 23/3677; H01L 23/3738; H01L 21/4857; H01L 21/56; H01L 23/3737; H01L 24/16; H01L 24/32; H01L 24/73; H01L 25/18; H01L 2224/16225; H01L 2224/32225; H01L 2224/73204; H01L 2924/1431; H05K 1/181; H10B 80/00

(57) ABSTRACT

Provided is a semiconductor package, including a first redistribution structure, a first chip on the first redistribution structure, a molding member on the first redistribution structure and surrounding the first chip, a conductive pillar penetrating through the molding member in a first direction, a second redistribution structure on a second surface of the molding member, a second chip on the second redistribution structure, and a heat dissipation chip at least partially overlapping the first chip in the vertical direction, wherein the second redistribution structure at least partially overlaps the heat dissipation chip in a second direction intersecting the first direction.

### CROSS-REFERENCE TO RELATED APPLICATION

This application claims priority to Korean Patent Application No. 10-2023-0122666, filed on Sep. 14, 2023, in the Korean Intellectual Property Office, the disclosure of which is incorporated by reference herein in its entirety.

### BACKGROUND

Embodiments of the present disclosure relate to a semiconductor package, and more particularly, to a semiconductor package having an enhanced heat dissipation characteristic.

Recently, in the field of electronic products, the demand for portable devices is increasing rapidly, and thus, the miniaturization and lightness of electronic products equipped in electronic products have been continuously needed. To realize the miniaturization and lightness of electronic products, it is necessary that semiconductor packages equipped in electronic products have smaller volume and process high-capacity data. As semiconductor packages are more and more miniaturized and lightweight, research on semiconductor packages capable of easily dissipating heat occurring therein has been conducted.

### SUMMARY

One or more embodiments provide a semiconductor package having an improved heat characteristic.

The object of the present disclosure is not limited to the aforesaid, but other objects not described herein will be clearly understood by those of ordinary skill in the art from descriptions below.

According to an aspect of an embodiment, there is provided a semiconductor package, including a first redistribution structure, a first chip on the first redistribution structure, a molding member on the first redistribution structure and surrounding the first chip, a conductive pillar penetrating through the molding member in a first direction, a second redistribution structure on a second surface of the molding member, a second chip on the second redistribution structure, and a heat dissipation chip at least partially overlapping the first chip in the vertical direction, wherein the second redistribution structure at least partially overlaps the heat dissipation chip in a second direction intersecting the first direction.

According to another aspect of an embodiment, there is provided a semiconductor package including a first redistribution structure, a first chip on the first redistribution structure, a molding member on the first redistribution structure and surrounding the first chip, a conductive pillar penetrating through the molding member in a first direction, a second redistribution structure on a first surface of the molding member, a second chip on the second redistribution structure, and a heat dissipation chip on the second redistribution structure and spaced apart from the second chip in a second direction that intersects the first direction to at least partially overlap the first chip in the first direction, wherein the second redistribution structure includes a second redistribution insulation layer, a second redistribution pattern, and a heat conduction pattern, wherein the second redistribution pattern electrically connects the second chip with the conductive pillar, and wherein the heat conduction pattern penetrates through the second redistribution structure in the vertical direction from the first surface of the molding member to a second surface of the heat dissipation chip.

According to another aspect of an embodiment, there is provided a semiconductor package including a first redistribution structure, a first chip on the first redistribution structure, a molding member on the first redistribution structure and surrounding the first chip, a conductive pillar arranged spaced apart from the first chip in a second direction to penetrate through the molding member in a first direction intersecting the second direction, a second redistribution structure on an upper surface of the molding member, a second chip on the second redistribution structure, a heat dissipation chip on the second redistribution structure and spaced apart from the second chip in the second direction to at least partially overlap the first chip in the vertical direction, and a thermal interfacial material (TIM) layer between the heat dissipation chip and the second redistribution structure, wherein the second redistribution structure includes a second redistribution insulation layer, a second redistribution pattern, and a heat conduction pattern, wherein the heat conduction pattern is electrically disconnected to the first chip, wherein the second redistribution pattern electrically connects the second chip to the conductive pillar, wherein the heat conduction pattern penetrates through the second redistribution structure in the first direction from the first surface of the molding member to a second surface of the heat dissipation chip, and wherein the first chip includes a logic chip, the second chip includes a memory chip, and the heat dissipation chip includes silicon . . .

### BRIEF DESCRIPTION OF DRAWINGS

Embodiments will be more clearly understood from the following detailed description taken in conjunction with the accompanying drawings in which:

FIG. 1A is a cross-sectional view illustrating a semiconductor package according to an embodiment;

FIG. 1B is an enlarged view of a region AA of FIG. 1A;

FIG. 2A is a plan view illustrating a semiconductor package according to an embodiment;

FIG. 2B is a cross-sectional view of the semiconductor package taken along line A1-A1′ of FIG. 2A;

FIG. 3 is a cross-sectional view illustrating a semiconductor package according to an embodiment;

FIG. 4 is a cross-sectional view illustrating a semiconductor package according to an embodiment;

FIGS. 5A, 5B, 5C, 5D, 5E, 5F, and 5G are cross-sectional views illustrating a method of manufacturing a semiconductor package, according to an embodiment;

FIG. 6 is a cross-sectional view illustrating a semiconductor package according to an embodiment;

FIG. 7 is a cross-sectional view illustrating a semiconductor package according to an embodiment;

FIG. 8 is a cross-sectional view illustrating a semiconductor package according to an embodiment;

FIG. 9 is a cross-sectional view illustrating a semiconductor package according to an embodiment; and

FIGS. 10A, 10B, 10C, 10D, 10E, and 10F are cross-sectional views illustrating a method of manufacturing a semiconductor package, according to an embodiment.

### DETAILED DESCRIPTION

Hereinafter, embodiments will be described in detail with reference to the accompanying drawings. Like reference numerals refer to like elements in the drawings, and their repeated descriptions are omitted.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

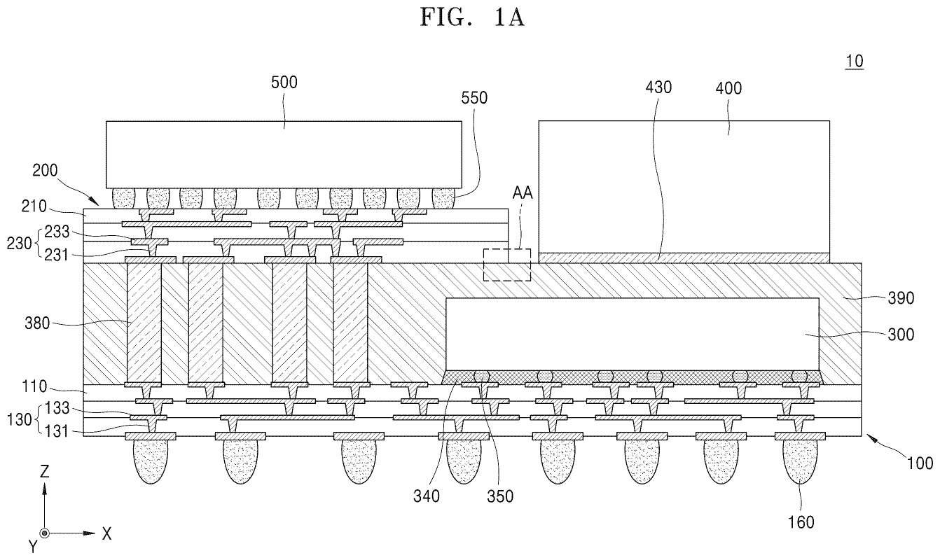

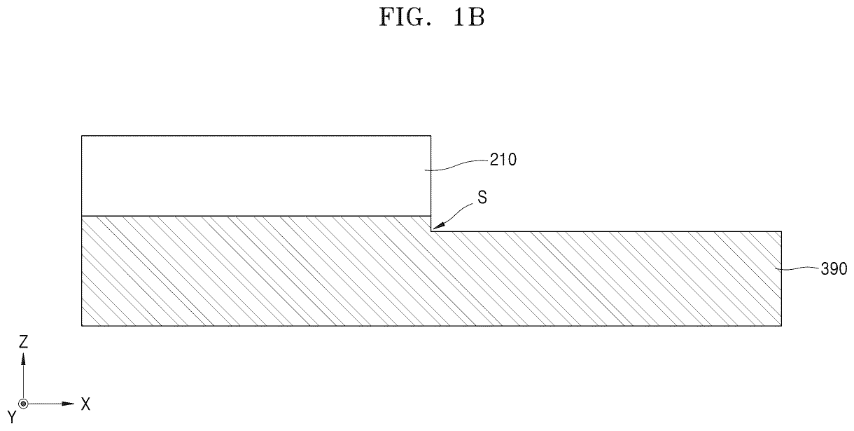

FIG. 1A is a cross-sectional view illustrating a semiconductor package 10 according to an embodiment. FIG. 1B is an enlarged view of a region AA of FIG. 1A.

Referring to FIGS. 1A and 1B, the semiconductor package 10 according to an embodiment may include a first redistribution structure 100, a first chip 300, a molding member 390, a conductive pillar 380, a second redistribution structure 200, a heat dissipation chip 400, and a second chip 500.

The first redistribution structure 100 may include an upper surface and a lower surface which are opposite to each other, and at least one of the upper surface and the lower surface may be a planar surface. The first redistribution structure 100 may be disposed under the first chip 300 and may electrically connect the first chip 130 with an external connection terminal 160 and the conductive pillar 380 with the external connection terminal 160.

The first redistribution structure 100 may include a first redistribution insulation layer 110 and a first redistribution pattern 130. The first redistribution insulation layer 110 may include a plurality of layers which are stacked in the vertical direction Z, and the first redistribution pattern 130 may include the stacked insulation layers.

In the following drawings, a direction in which a plurality of first redistribution insulation layers 110 are stacked may be understood as a Z-axis direction, and an X-axis direction and a Y-axis direction may be understood as directions perpendicular to each other in a plane which has the Z-axis direction as a normal vector. That is, the X-axis direction and the Y-axis direction may each represent a direction parallel to a surface of an upper surface or a lower surface of the first redistribution structure 100. For example, the Z-axis direction may be a direction perpendicular to the surface of the upper surface or the lower surface of the first redistribution structure 100 and may represent a direction perpendicular to an X-Y plane. Also, in the following drawings, a first horizontal direction, a second horizontal direction, and a vertical direction may be understood as follows. The first horizontal direction may be understood as the X-axis direction, a second horizontal direction may be understood as the Y-axis direction, and the vertical direction may be understood as the Z-axis direction.

According to embodiments, the first redistribution insulation layer 110 may include a plurality of layers and may be mutually stacked and provided in the vertical direction Z. The first redistribution insulation layer 110 may be formed from, for example, a photo imageable dielectric (PID) or a photosensitive polyimide (PSPI).

The first redistribution pattern 130 may be formed in each of the plurality of first redistribution insulation layers 110 mutually stacked in the vertical direction Z. The first redistribution pattern 130 may include, for example, metal such as copper (Cu), aluminum (Al), tungsten (W), titanium (Ti), tantalum (Ta), indium (In), molybdenum (Mo), manganese (Mn), cobalt (Co), zinc (Sn), nickel (Ni), magnesium (Mg), rhenium (Re), beryllium (Be), gallium (Ga), or ruthenium (Ru), or a metal alloy, but is not limited thereto. In some embodiments, the first redistribution pattern 130 may be formed by stacking metal or a metal alloy on a seed layer including Cu, Ti, titanium nitride, or titanium tungsten.

The first redistribution pattern 130 may include a first redistribution line pattern 133 and a first redistribution via pattern 131. The first redistribution line pattern 133 may extend in the first horizontal direction X, and the first redistribution via pattern 131 may extend in the vertical direction Z. The first redistribution pattern 130 may have a multi-layer structure where the first redistribution line pattern 133 and the first redistribution via pattern 131 are alternately stacked. The first redistribution line pattern 133 may have a shape which extends in a horizontal direction along a surface of at least one of an upper surface and a lower surface of each of the first redistribution insulation layers 110. The first redistribution via pattern 131 may have a shape which penetrates through the first redistribution insulation layer 110 in the vertical direction Z. The first redistribution via pattern 131 may physically connect the first redistribution line patterns 133, disposed at different levels in the vertical direction Z, with each other. In some embodiments, at least some of the first redistribution line patterns 133 may be formed along with some of the first redistribution via patterns 131 and may be provided as one body. According to embodiments, the first redistribution via pattern 131 may have a tapered shape where a horizontal width narrows progressively as a level in the vertical direction Z is reduced. However, a shape of the first redistribution via pattern 131 is not limited thereto, and the first redistribution via pattern 131 may have a shape where a horizontal width increases progressively as a level in the vertical direction Z is reduced, or the horizontal width is constant regardless of the level in the vertical direction Z. The first redistribution pattern 130 may be physically connected with and contact the conductive pillar 380 and the first chip 300.

In some embodiments, the first redistribution structure 100 may be a printed circuit board (PCB). In this case, the first redistribution insulation layer 110 may include at least one material selected from among phenol resin, epoxy resin, and polyimide. The first redistribution insulation layer 110 may include, for example, at least one material selected from among frame retardant 4 (FR-4), tetrafunctional epoxy, polyphenylene ether, epoxy/polyphenylene oxide, bismaleimide triazine (BT), thermount, cyanate ester, polyimide, and liquid crystal polymer. Also, the first redistribution pattern 130 may include Cu, Ni, stainless steel, or beryllium copper.

The external connection terminal 160 may be disposed at a lower portion of the first redistribution structure 100. The external connection terminal 160 may be connected with an external device (for example, a mother board). The external connection terminal 160 may be physically connected with and contact the first redistribution pattern 130. The external connection terminal 160 may transfer an electrical signal, transferred from the first chip 300, the heat dissipation chip 400, and the second chip 500, to an external device through the first redistribution pattern 130, or may transfer an electrical signal, transferred from the external device, to the first chip 300, the heat dissipation chip 400, and the second chip 500. The external connection terminal 160 may include a conductive material, and for example, may include at least one of a solder, Sn, silver (Ag), Cu, and Al.

The first chip 300 may be mounted on an upper surface of the first redistribution structure 100. The first chip 300 may be electrically connected with the first redistribution pattern 130. According to embodiments, the first chip 300 may be mounted on the first redistribution structure 100 as a flip chip type. For example, the first chip 300 may be mounted on, as a flip chip type, the first redistribution structure 100 through a first bump 350. According to embodiments, the first bump 350 and a first under-fill material layer 340 surrounding the first bump 350 may be disposed between the first chip 300 and the first redistribution structure 100. The first under-fill material layer 340 may fix the first bump 350. The first under-fill material layer 340 may include, for example, epoxy resin formed by a capillary under-fill process. However, embodiments are not limited thereto, and in some embodiments, the molding member 390 may be directly filled into a gap between the first chip 300 and the first redistribution structure 100 through a molded under-fill process. In this case, the first under-fill material layer 340 may be omitted.

According to embodiments, the first chip 300 may cause more heat than the second chip 500. The first chip 300 may be a logic chip. The logic chip may be, for example, a microprocessor such as a central processing unit (CPU), a graphics processing unit (GPU), or an application processor (AP), an analog device, or a digital signal processor.

However, the first chip 300 is not limited thereto and may include a memory chip. The memory chip may be, for example, a volatile memory chip, such as dynamic random access memory (DRAM) or static random access memory (SRAM), or a non-volatile memory chip such as phase-change random access memory (PRAM), magnetoresistive random access memory (MRAM), ferroelectric random access memory (FeRAM), or resistive random access memory (RRAM).

The molding member 390 may be formed to surround the first chip 300, on the upper surface of the first redistribution structure 100. According to embodiments, the molding member 390 may surround and be provided at a side surface and an upper surface of the first chip 300. The molding member 390 may include thermocurable resin such as epoxy resin, thermoplastic resin such as polyimide, or resin including a reinforcing agent such as an inorganic filler, and in detail, may include Ajinomoto build-up film (ABF), frame retardant 4 (FR-4), or bismaleimide triazine (BT), but is not limited thereto and the molding member 390 may include a molding material, such as epoxy mold compound (EMC), or a photosensitive material such as photoimagable encapsulant (PIE). In some embodiments, a portion of the molding member 390 may include an insulating material such as silicon oxide, silicon nitride, or silicon oxynitride.

According to embodiments, a step height S may be formed on an upper surface of the molding member 390. For example, a level in the vertical direction Z of a portion, overlapping the second redistribution structure 200 in the vertical direction Z, of the upper surface of the molding member 390 may be higher than a level in the vertical direction Z of a portion, which does not overlap the second redistribution structure 200 in the vertical direction Z, of the upper surface of the molding member 390. A thermal interfacial material (TIM) layer 430 may overlap the second redistribution structure 200 in the first horizontal direction X, based on the step height S.

The conductive pillar 380 may be arranged spaced apart from the first chip 300 in a horizontal direction, on the upper surface of the first redistribution structure 100. According to embodiments, the conductive pillar 380 may include plurality. The plurality of conductive pillars 380 may be arranged spaced apart from one another at a certain interval in the horizontal direction. The conductive pillar 380 may have a shape which extends in the vertical direction Z and may penetrate through the molding member 390 in the vertical direction Z.

The conductive pillar 380 may electrically connect the second redistribution structure 200 with the first redistribution structure 100. For example, the conductive pillar 380 may be a vertical connection conductor for electrically connecting the second redistribution structure 200 with the first redistribution structure 100. According to embodiments, an upper surface of the conductive pillar 380 may be on the same plane as the upper surface of the molding member 390.

The second redistribution structure 200 may be disposed on the upper surface of the molding member 390. The second redistribution structure 200 may include an upper surface and a lower surface, which are opposite to each other, and at least one of the upper surface and the lower surface may be a planar surface. According to embodiments, the second redistribution structure 200 may be disposed to overlap the heat dissipation chip 400 in the first horizontal direction X. The second redistribution structure 200 may be spaced apart from the heat dissipation chip 400 by a certain interval in the first horizontal direction X. A length of the second redistribution structure 200 in the first horizontal direction X may be less than a length of the molding member 390 in the first horizontal direction X.

The second redistribution structure 200 may electrically connect the conductive pillar 380 with the second chip 500. The second redistribution structure 200 may include a second redistribution insulation layer 210 and a second redistribution pattern 230. The second redistribution structure 200 may electrically connect the conductive pillar 380 with the second chip 500 through the second redistribution pattern 230. The second redistribution insulation layer 210 may include a plurality of layers which are stacked in the vertical direction Z. The second redistribution pattern 230 may include a second redistribution via pattern 231 and a second redistribution line pattern 233.

The second redistribution insulation layer 210 and the second redistribution pattern 230 may be substantially the same as or similar to the first redistribution insulation layer 110 and the first redistribution pattern 130 described above, and thus, repeated descriptions thereof are omitted.

The heat dissipation chip 400 may be spaced apart from the second redistribution structure 200 in the first horizontal direction X, on the upper surface of the molding member 390. The TIM layer 430 may be disposed between the heat dissipation chip 400 and the molding member 390. The TIM layer 430 may fix the heat dissipation chip 400 to the upper surface of the molding member 390. According to embodiments, the TIM layer 430 may include an insulating material, or may include a material capable of maintaining electrical insulating properties, in addition to an insulating material. The TIM layer 430 may include, for example, an insulation base layer such as epoxy resin and a heat dissipation filler included in the insulation base layer. The TIM layer 430 may be, for example, mineral oil, grease, gap filler putty, phase change gel, phase change material pads, or particle filled epoxy.

According to embodiments, the heat dissipation chip 400 may be a dummy chip and may include Si. The heat dissipation chip 400 may include a material having a relatively high thermal conductance. According to embodiments, a level in the vertical direction Z of an upper surface of the heat dissipation chip 400 may be substantially the same as a level in the vertical direction Z of an upper surface of the second chip 500. A thickness of the heat dissipation chip 400 in the vertical direction Z may be thicker than that of the second chip 500 in the vertical direction Z.

The heat dissipation chip 400 may overlap the first chip 300 in the vertical direction Z. In some embodiments, the second redistribution structure 200 may not be disposed between the heat dissipation chip 400 and the molding member 390.

The second chip 500 may be disposed on an upper surface of the second redistribution structure 200 and may be disposed spaced apart from the heat dissipation chip 400 in the first horizontal direction X. According to embodiments, the second chip 500 may be a memory chip. The memory chip may be a volatile memory chip, such as DRAM or SRAM, or a non-volatile memory chip such as PRAM, MRAM, FeRAM, or RRAM. The second chip 500 may be mounted on, as a flip chip type, the upper surface of the second redistribution structure 200 through a second bump 550. In some embodiments, an under-fill material layer surrounding the second bump 550 may be disposed between the second chip 500 and the second redistribution structure 200. According to embodiments, the second chip 500 may receive a power signal from an external device through the second redistribution pattern 230 connected with the conductive pillar 380.

In the semiconductor package 10 according to an embodiment, the second redistribution structure 200 may not be disposed between the heat dissipation chip 400 and the first chip 300, and thus, heat occurring in the first chip 300 may be more easily dissipated upward in the vertical direction Z along the molding member 390 and the heat dissipation chip 400. Also, because the second redistribution structure 200 is not disposed between the heat dissipation chip 400 and the first chip 300, the heat dissipation chip 400 disposed on the upper surface of the molding member 390 may increase in thickness in the vertical direction Z. The heat dissipation chip 400 may include a material which has a relatively high thermal conductance, and thus, heat occurring in the semiconductor package 10 may be more easily dissipated to the outside than a case where the second redistribution structure 200 is disposed between the heat dissipation chip 400 and the first chip 300.

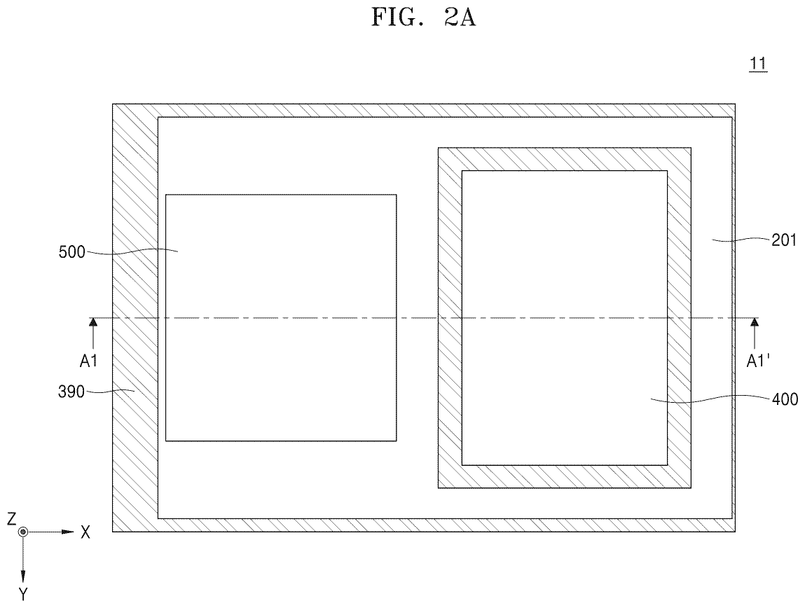

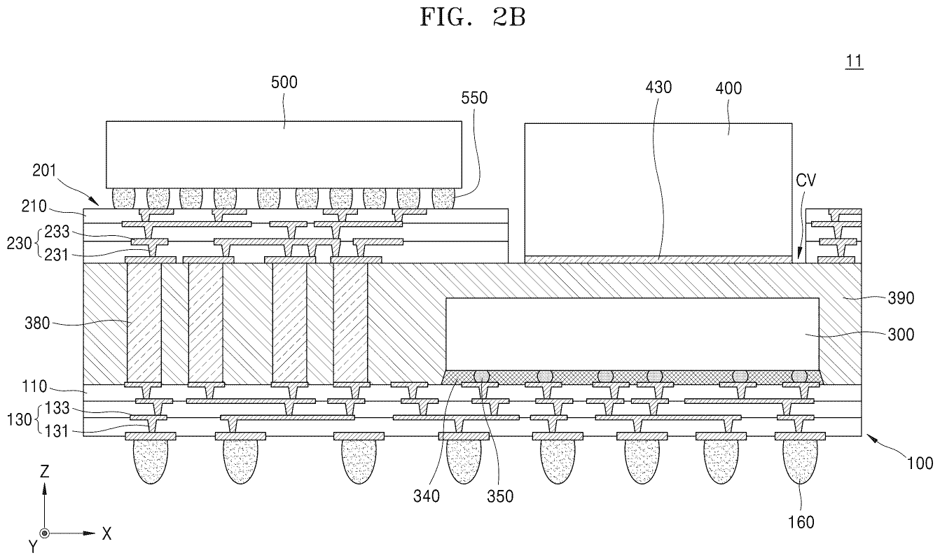

FIG. 2A is a plan view illustrating a semiconductor package 11 according to an embodiment. FIG. 2B is a cross-sectional view taken along line A1-A1′ of FIG. 2A. Hereinafter, descriptions of the semiconductor package 11 of FIGS. 2A and 2B which are the same as or similar to the descriptions of the semiconductor package 10 described above with reference to FIGS. 1A and 1B are omitted, and a difference therebetween will be mainly described.

Referring to FIGS. 2A and 2B, the semiconductor package 11 may include a first redistribution structure 100, a first chip 300, a molding member 390, a conductive pillar 380, a second redistribution structure 201, a heat dissipation chip 400, and a second chip 500.

The first redistribution structure 100 may be disposed under the first chip 300 in the vertical direction Z and may include a first redistribution insulation layer 110 and a first redistribution pattern 130. The first redistribution insulation layer 110 may include a plurality of layers which are stacked in the vertical direction Z, and the first redistribution pattern 130 may include the stacked insulation layers. The first redistribution pattern 130 may include a first redistribution line pattern 133 and a first redistribution via pattern 131. The first chip 300 may be mounted on an upper surface of the first redistribution structure 100. The molding member 390 may be formed to surround the first chip 300, on the upper surface of the first redistribution structure 100. The conductive pillar 380 may penetrate through the molding member 390 in the vertical direction Z.

The second redistribution structure 201 may be disposed on an upper surface of the molding member 390 and may include a second redistribution insulation layer 210 and a second redistribution pattern 230. The second redistribution pattern 230 may include a second redistribution via pattern 231 and a second redistribution line pattern 233. The second redistribution structure 201 may include a cavity CV which extends in the vertical direction Z from an upper surface of the second redistribution structure 201 up to a lower surface of the second redistribution structure 201. That is, the cavity CV may be formed to penetrate through the second redistribution structure 201 in the vertical direction Z. The heat dissipation chip 400 may be disposed in the cavity CV. The heat dissipation chip 400 may be disposed at a portion, exposed upward in the vertical direction Z by the second redistribution structure 201, of the upper surface of the molding member 390. The second redistribution structure 201 may surround the heat dissipation chip 400 on an X-Y plane. The second redistribution structure 201 may be spaced apart from the heat dissipation chip 400 in a horizontal direction (X, Y).

A level in the vertical direction Z of a portion, overlapping the second redistribution structure 201 in the vertical direction Z, of the upper surface of the molding member 390 may be higher than a level in the vertical direction Z of a portion, which does not overlap the second redistribution structure 201 in the vertical direction Z, of the upper surface of the molding member 390.

In the semiconductor package 11 according to an embodiment, the cavity CV may be formed in only a region, where the heat dissipation chip 400 is disposed, of the second redistribution structure 201, and thus, the second redistribution pattern 230 may be formed at the other portion, where the heat dissipation chip 400 is not disposed, of the second redistribution structure 201. Accordingly, the second redistribution pattern 230 may be formed at a relatively high density, and a region etched by the second redistribution structure 201 may be minimized.

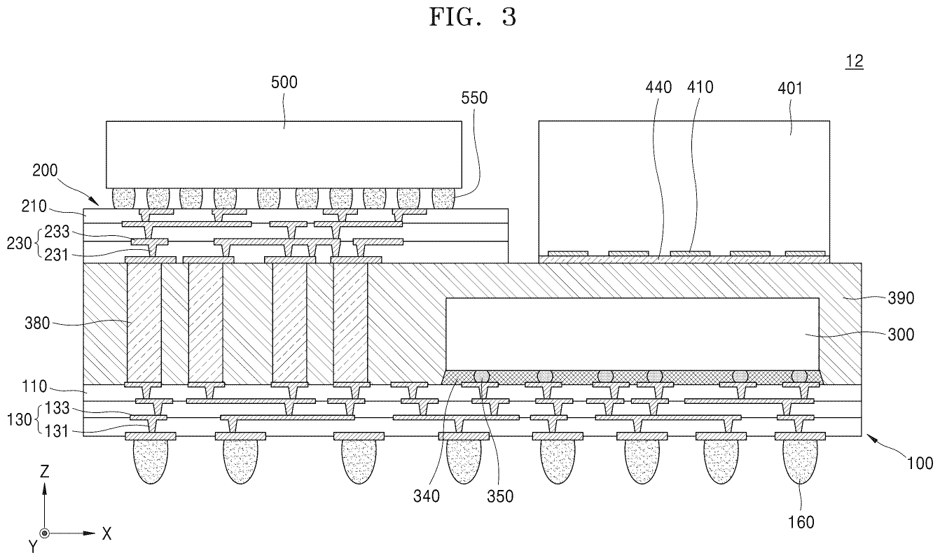

FIG. 3 is a cross-sectional view illustrating a semiconductor package 12 according to an embodiment. Hereinafter, descriptions of the semiconductor package 12 of FIG. 3 which are the same as or similar to the descriptions of the semiconductor package 11 described above with reference to FIG. 2 are omitted, and a difference therebetween will be mainly described.

Referring to FIG. 3, the semiconductor package 12 may include a first redistribution structure 100, a first chip 300, a molding member 390, a conductive pillar 380, a second redistribution structure 200, a heat dissipation chip 401, an adhesive layer 440, and a second chip 500.

The first redistribution structure 100 may be disposed under the first chip 300 in the vertical direction Z and may include a first redistribution insulation layer 110 and a first redistribution pattern 130. The first redistribution insulation layer 110 may include a plurality of layers which are stacked in the vertical direction Z, and the first redistribution pattern 130 may include the stacked insulation layers. The first redistribution pattern 130 may include a first redistribution line pattern 133 and a first redistribution via pattern 131. The first chip 300 may be mounted on an upper surface of the first redistribution structure 100. The molding member 390 may be formed to surround the first chip 300, on the upper surface of the first redistribution structure 100. The conductive pillar 380 may penetrate through the molding member 390 in the vertical direction Z. The second redistribution structure 200 may be disposed on an upper surface of the molding member 390 and may include a second redistribution insulation layer 210 and a second redistribution pattern 230. The second redistribution pattern 230 may include a second redistribution via pattern 231 and a second redistribution line pattern 233. The heat dissipation chip 401 may be disposed at a portion, exposed upward in the vertical direction Z by the second redistribution structure 200, of the upper surface of the molding member 390. A heat dissipation chip pad 410 may be formed on a lower surface of the heat dissipation chip 401. The heat dissipation chip pad 410 may include a material having a relatively high thermal conductance. According to embodiments, the heat dissipation chip pad 410 may include Cu. The adhesive layer 440 may be disposed between the heat dissipation chip 401 and the molding member 390. The adhesive layer 440 may surround the heat dissipation chip pad 410 and may fix the heat dissipation chip 401 to the upper surface of the molding member 390. According to embodiments, the adhesive layer 440 may be a film autonomously having an adhesive characteristic. For example, the adhesive layer 440 may be a double-sided adhesive film. According to embodiments, the adhesive layer 440 may be a tape-shaped material layer, a liquid coating curing material layer, or a combination thereof. Also, the adhesive layer 440 may include a thermal setting structure, thermal plastic, a ultraviolet (UV) cure material, or a combination thereof. The adhesive layer 440 may be referred to as a die attach film (DAF) or a non-conductive film (NCF).

In the semiconductor package 12 according to an embodiment, the heat dissipation chip pad 410 may be formed on a lower surface of the heat dissipation chip 401, and the heat dissipation chip 401 may be fixed to the upper surface of the molding member 390 by the adhesive layer 440. The heat dissipation chip pad 410 may include a material having a relatively high heat conductance, and thus, heat occurring in the first chip 300 may be more easily dissipated upward in the vertical direction Z along the adhesive layer 440, the heat dissipation chip pad 410, and the heat dissipation chip 401.

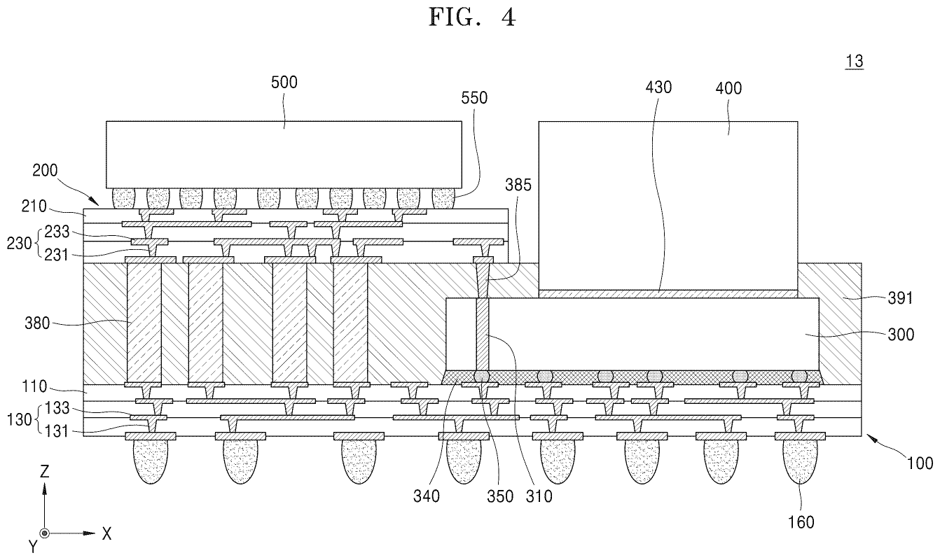

FIG. 4 is a cross-sectional view illustrating a semiconductor package 13 according to an embodiment. Hereinafter, descriptions of the semiconductor package 13 of FIG. 4 which are the same as or similar to the descriptions of the semiconductor package 12 described above with reference to FIG. 3 are omitted, and a difference therebetween will be mainly described.

Referring to FIG. 4, the semiconductor package 13 may include a first redistribution structure 100, a first chip 300, a molding member 391, a conductive pillar 380, a second redistribution structure 200, a heat dissipation chip 400, and a second chip 500.

The first redistribution structure 100 may be disposed under the first chip 300 and may include a first redistribution insulation layer 110 and a first redistribution pattern 130. The first redistribution insulation layer 110 may include a plurality of layers which are stacked in the vertical direction Z, and the first redistribution pattern 130 may included in the stacked insulation layers. The first redistribution pattern 130 may include a first redistribution line pattern 133 and a first redistribution via pattern 131. The first chip 300 may be mounted on an upper surface of the first redistribution structure 100.

The molding member 391 may be formed to surround the first chip 300, on the upper surface of the first redistribution structure 100. The conductive pillar 380 may penetrate through the molding member 391 in the vertical direction Z. The second redistribution structure 200 may be disposed on an upper surface of the molding member 390 and may include a second redistribution insulation layer 210 and a second redistribution pattern 230. The second redistribution pattern 230 may include a second redistribution via pattern 231 and a second redistribution line pattern 233. The heat dissipation chip 400 may be disposed on an upper surface of the first chip 300. That is, the molding member 391 may not be disposed between the heat dissipation chip 400 and the first chip 300. The molding member 391 may surround at least a portion of a sidewall of the first chip 300. A portion of an upper surface of the first chip 300 may be exposed upward in the vertical direction Z by the molding member 391, and the heat dissipation chip 400 may be mounted on a region exposed upward in the vertical direction Z by the molding member 391. A TIM layer 430 may be disposed between the heat dissipation chip 400 and the first chip 300.

The first chip 300 may further include a first through via 310. The first through via 310 may be formed to penetrate through the first chip 300 in the vertical direction Z. The first through via 310 may have a shape which extends in the vertical direction Z. The first through via 310 may be a through silicon via (TSV).

The first through via 310 may be physically connected with and contact a second through via 385. The second through via 385 may be formed on an upper surface of the first through via 310. The second through via 385 may be formed to penetrate through the molding member 391 in the vertical direction Z from the upper surface of the molding member 391 up to an upper surface of the first chip 300. The second redistribution pattern 230 may be physically connected with and contact the second through via 385. The second redistribution pattern 230 may be electrically connected with the first chip 300 through the second through via 385 and the first through via 310.

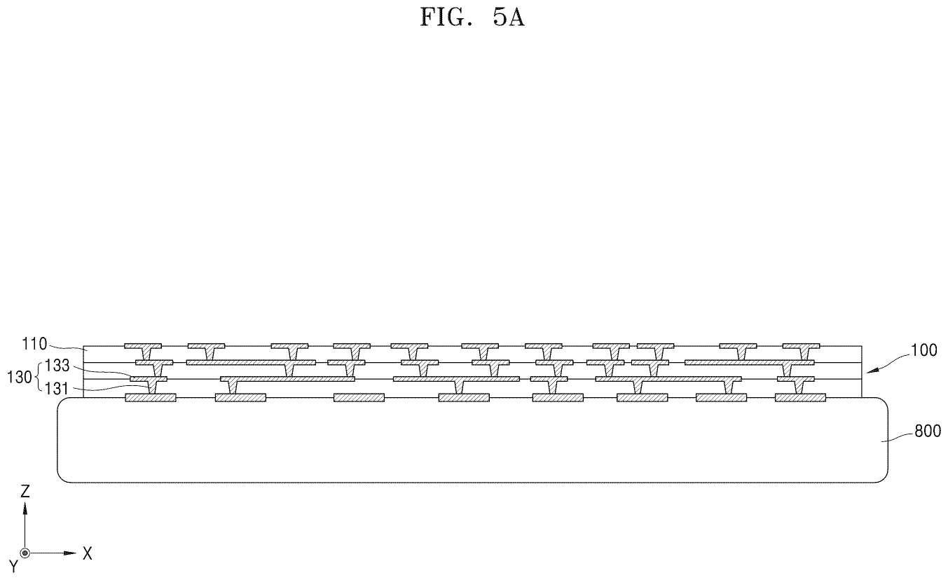

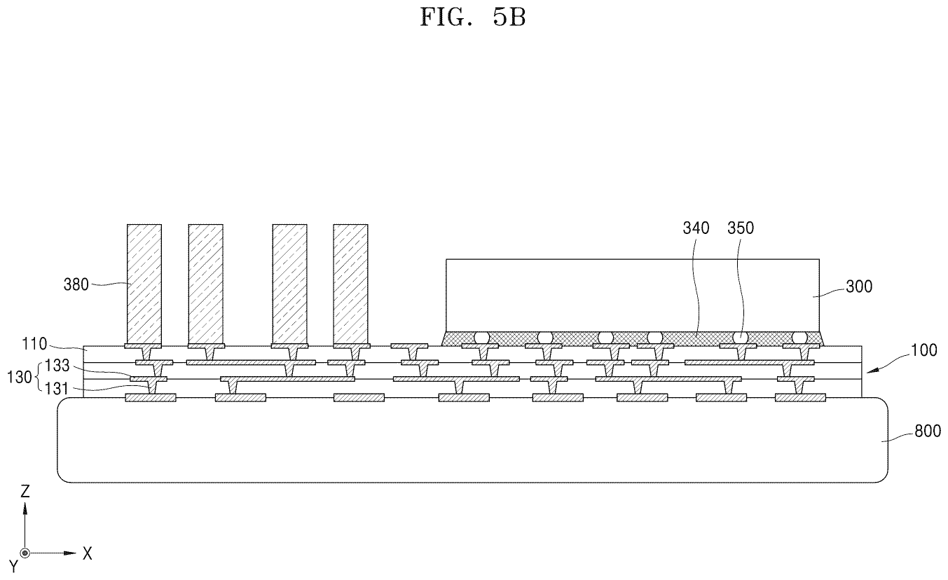

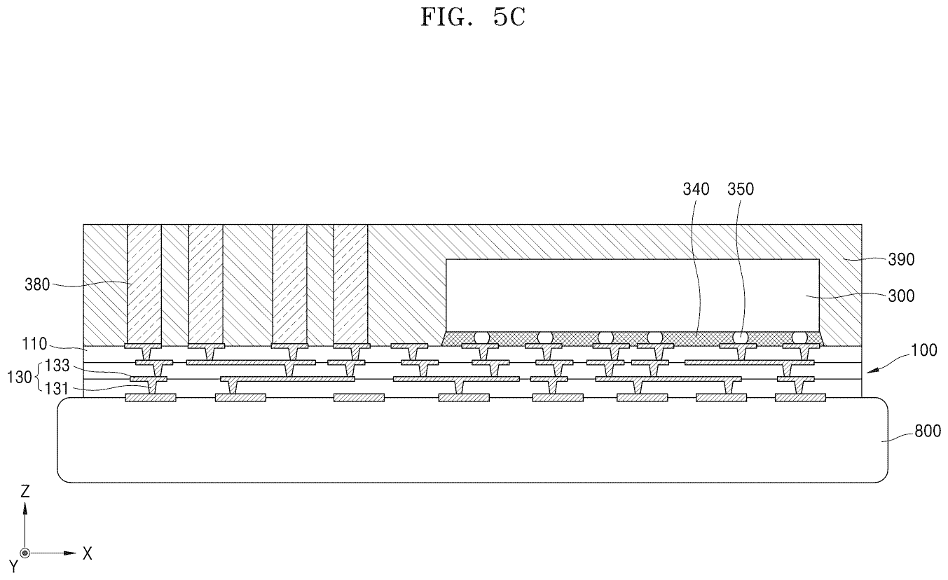

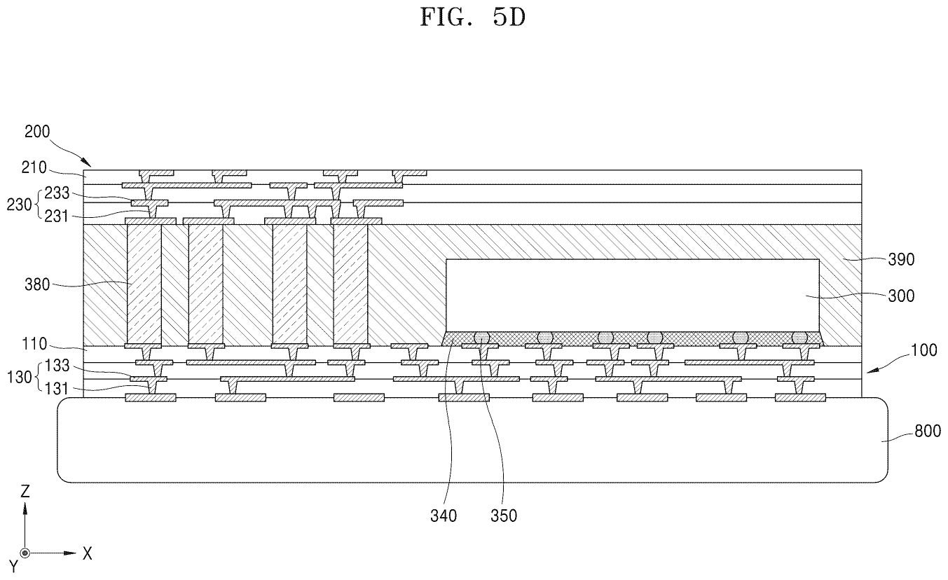

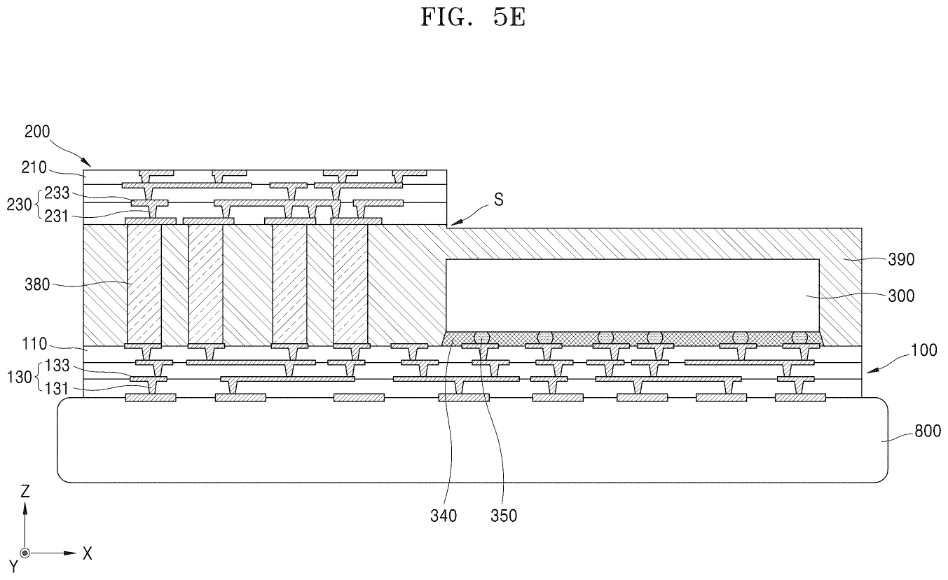

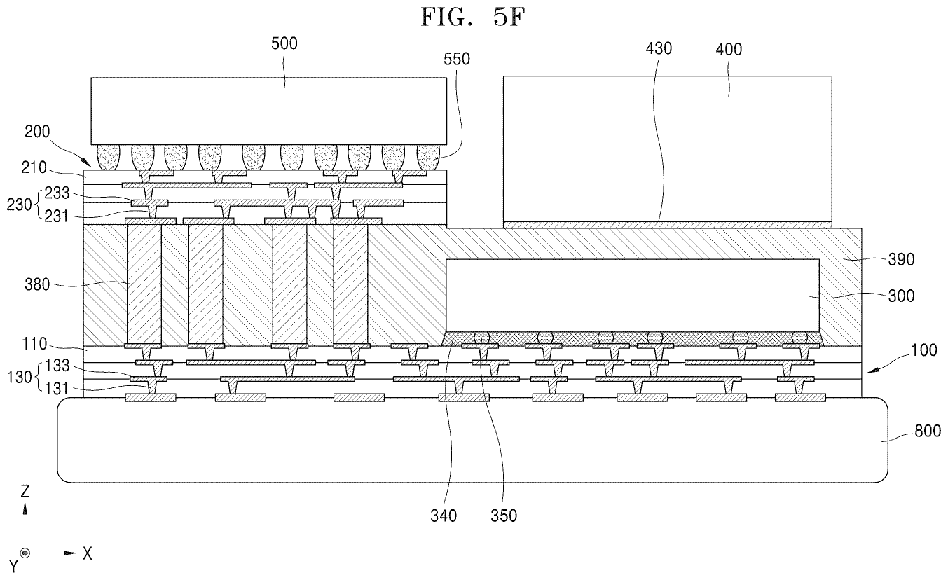

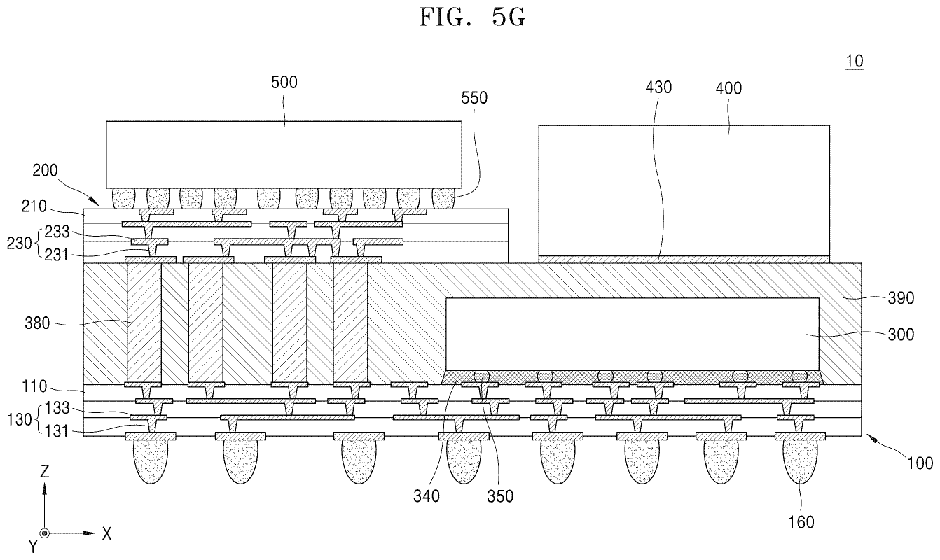

FIGS. 5A to 5G are cross-sectional views illustrating a method of manufacturing a semiconductor package, according to an embodiment. Hereinafter, descriptions which are the same as or similar to the descriptions of FIGS. 1A and 1B are omitted.

Referring to FIG. 5A, a first redistribution structure 100 may be formed on a carrier substrate 800. The carrier substrate 800 may be a circular substrate having a large size similar to a wafer. According to embodiments, a first redistribution insulation layer 110 may be formed by coating a photosensitive polyimide film on the carrier substrate 800. Subsequently, an opening may be formed by etching the first redistribution insulation layer 110, based on a pattern, and then, a first redistribution pattern 130 may be formed by filling metal into the opening. According to embodiments, the first redistribution insulation layer 110 may include a plurality of layers.

Referring to FIG. 5B, a conductive pillar 380 may be formed on an upper surface of the first redistribution structure 100, and the first chip 300 may be mounted on the first redistribution structure 100 to be spaced apart from the conductive pillar 380 in the first horizontal direction X. Each of the conductive pillar 380 and the first chip 300 may be physically connected with and contact the first redistribution pattern 130. According to embodiments, the conductive pillar 380 may be formed by an electroplating process by using seed metal formed on the first redistribution structure 100. According to embodiments, the seed metal may include Cu, Ti, Ta, titanium nitride (TiN), and tantalum nitride (TaN). First, a photoresist (PR) may be coated on the seed metal, and after am exposure process is performed, the PR may be developed. For example, the PR may be a positive PR. An exposed portion may be removed through a development process, and thus, a through hole may be formed and the seed metal may be exposed from the PR through the through hole. Subsequently, the conductive pillar 380 extending in the vertical direction Z may be formed through a plating process. After the conductive pillar 380 is formed, a PR pattern may be removed. The PR pattern may be removed through a strip/ashing process. After the PR pattern is removed, the seed metal may be exposed between adjacent conductive pillars 380. Continuously, the exposed seed metal may be removed through an etching process. An upper surface of the first redistribution structure 100 may be exposed by removing the seed metal. Furthermore, the seed metal on a lower surface of the conductive pillar 380 may be maintained.

The first chip 300 may be mounted on the first redistribution structure 100 as a flip chip type. However, embodiments are not limited thereto, and by coupling a pad of the first chip 300 to a pattern of the first redistribution structure 100 through direct bonding, the first chip 300 may be mounted on the first redistribution structure 100.

Referring to FIG. 5C, the conductive pillar 380 and a molding member 390 covering the first chip 300 may be formed, and the molding member 390 may be grinded so that an upper surface of the conductive pillar 380 is exposed upward in the vertical direction Z.

Referring to FIG. 5D, a second redistribution structure 200 may be formed on the upper surface of the molding member 390. A second redistribution insulation layer 210 may be formed to overlap the first chip 300 in the vertical direction Z. According to embodiments, a length of the second redistribution insulation layer 210 in the first horizontal direction X may be formed to be substantially equal to that of the molding member 390 in the first horizontal direction X.

A second redistribution pattern 230 may be formed not to overlap the first chip 300 in the vertical direction Z. The second redistribution pattern 230 may be formed in a plurality of second redistribution insulation layers 210 and may not be formed in a region, overlapping the first chip 300 in the vertical direction Z, of the second redistribution insulation layer 210.

Referring to FIG. 5D, a certain region may be etched downward in the vertical direction Z in the second redistribution structure 200. According to embodiments, a region, overlapping the first chip 300 in the vertical direction Z, of the second redistribution structure 200 may be etched. In this case, the etched region of the second redistribution structure 200 may be a region where the second redistribution pattern 230 is not formed. For example, only the second redistribution insulation layer 210 may be etched by the etching.

A portion of the upper surface of the molding member 390 may also be etched by etching. A step height S may be formed on the upper surface of the molding member 390 through the etching. Because the step height S is formed by the etching of the second redistribution insulation layer 210, an upper portion of the molding member contacting a portion, overlapping the second redistribution insulation layer 210 in the vertical direction Z, of the molding member 390 (i.e., a portion where the second redistribution insulation layer is not etched) may have a level in the vertical direction Z which is higher than a level in the vertical direction Z of a periphery.

Referring to FIGS. 5F and 5G, a second chip 500 may be mounted on an upper surface of the second redistribution structure 200, and a heat dissipation chip 400 may be mounted on the upper surface of the molding member 390. A region with the heat dissipation chip 400 mounted thereon may be a portion, exposed upward in the vertical direction Z by the etching of the second redistribution insulation layer 210, of the upper surface of the molding member 390. The heat dissipation chip 400 may be attached on the upper surface of the molding member 390 through the TIM layer 430. Subsequently, the carrier substrate 800 may be removed, and an external connection terminal 160 may be formed on a lower surface of the first redistribution structure 100, thereby manufacturing the semiconductor package 10.

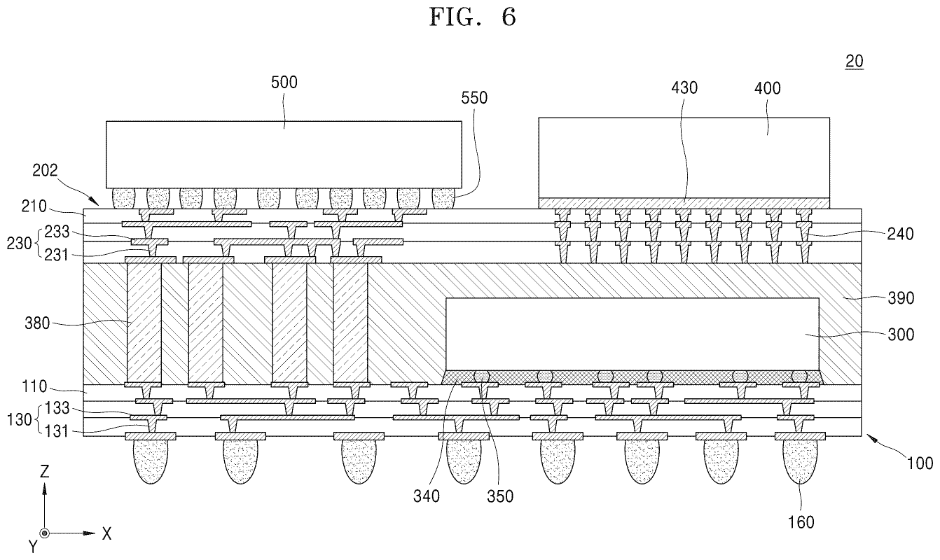

FIG. 6 is a cross-sectional view illustrating a semiconductor package 20 according to an embodiment. Hereinafter, descriptions of the semiconductor package 20 of FIG. 6 which are the same as or similar to the descriptions of the semiconductor package 10 described above with reference to FIGS. 1A and 1B are omitted, and a difference therebetween will be mainly described.

Referring to FIG. 6, the semiconductor package 20 may include a first chip 300, a molding member 390, a conductive pillar 380, a second redistribution structure 202, a heat dissipation chip 400, and a second chip 500.

The first redistribution structure 100 may be disposed under the first chip 300 and may include a first redistribution insulation layer 110 and a first redistribution pattern 130. The first redistribution insulation layer 110 may include a plurality of layers which are stacked in the vertical direction Z, and the first redistribution pattern 130 may include the stacked insulation layers. The first redistribution pattern 130 may include a first redistribution line pattern 133 and a first redistribution via pattern 131. The first chip 300 may be mounted on an upper surface of the first redistribution structure 100. The molding member 390 may be formed to surround the first chip 300, on the upper surface of the first redistribution structure 100. The conductive pillar 380 may penetrate through the molding member 390 in the vertical direction Z.

The second redistribution structure 202 may be disposed on the upper surface of the molding member 390. According to embodiments, the second redistribution structure 202 may include a second redistribution insulation layer 210, a second redistribution pattern 230, and a heat conduction pattern 240. The second redistribution insulation layer 210 may extend in the first horizontal direction X and may overlap the first chip 300 in the vertical direction Z. The second redistribution pattern 230 may be formed in the second redistribution insulation layer 210 and may be formed not to overlap the heat dissipation chip 400 in the vertical direction Z. The heat conduction pattern 240 may be formed in a region which overlaps the heat dissipation chip 400 in the vertical direction Z. The heat conduction pattern 240 may be formed to overlap the first chip 300 in the vertical direction Z. The heat conduction pattern 240 may be formed between the first chip 300 and the heat dissipation chip 400. The heat conduction pattern 240 may be formed to penetrate through the second redistribution insulation layer 210 up to a lower surface of the heat dissipation chip 400 from an upper surface of the molding member 390. According to embodiments, the heat conduction pattern 240 may include Cu. However, embodiments are not limited thereto, and the heat conduction pattern 240 may include a metal material having a high thermal conductance. The heat conduction pattern 240 may not be electrically connected with the first chip 300. The heat conduction pattern 240 may be formed in each of a plurality of second redistribution insulation layers 210 and may include a plurality of layers. That is, the heat conduction pattern 240 may be formed so that a plurality of heat conduction patterns 240 are stacked in the vertical direction Z. According to embodiments, the heat conduction pattern 240 may have a shape which extends in the vertical direction Z. In some embodiments, each of the heat conduction patterns 240 may have a tapered shape where a horizontal width narrows progressively as a level in the vertical direction Z is reduced.

The heat dissipation chip 400 may be fixed to an upper surface of the second redistribution structure 202 through the TIM layer 430. The heat dissipation chip 400 may be disposed on the heat conduction pattern 240 and may physically contact the heat conduction pattern 240 and the TIM layer 430.

In the semiconductor package 20 according to an embodiment, the heat conduction pattern 240 may be formed on the first chip 300 causing much heat and the heat dissipation chip 400 physically connected with and contact the heat conduction pattern 240 may be mounted on the first chip 300, and thus, heat occurring in the first chip 300 may be easily dissipated upward in the vertical direction Z.

Also, the heat conduction pattern 240 may be formed in the plurality of second redistribution insulation layers 210 and may have a shape which extends in the vertical direction Z, and thus, heat occurring in the semiconductor package 20 may be more easily transferred to the heat dissipation chip 400.

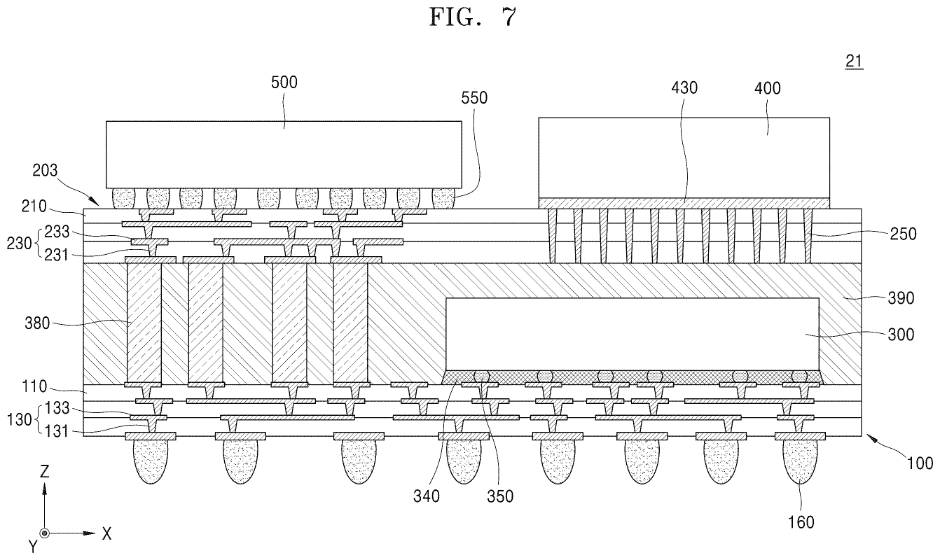

FIG. 7 is a cross-sectional view illustrating a semiconductor package 21 according to an embodiment. Hereinafter, descriptions of the semiconductor package 21 of FIG. 7 which are the same as or similar to the descriptions of the semiconductor package 20 described above with reference to FIG. 6 are omitted, and a difference therebetween will be mainly described.

Referring to FIG. 7, the semiconductor package 21 may include a first chip 300, a molding member 390, a conductive pillar 380, a second redistribution structure 203, a heat dissipation chip 400, and a second chip 500.

The first redistribution structure 100 may be disposed under the first chip 300 and may include a first redistribution insulation layer 110 and a first redistribution pattern 130. The first redistribution insulation layer 110 may include a plurality of layers which are stacked in the vertical direction Z, and the first redistribution pattern 130 may include the stacked insulation layers. The first redistribution pattern 130 may include a first redistribution line pattern 133 and a first redistribution via pattern 131. The first chip 300 may be mounted on an upper surface of the first redistribution structure 100. The molding member 390 may be formed to surround the first chip 300, on the upper surface of the first redistribution structure 100. The conductive pillar 380 may penetrate through the molding member 390 in the vertical direction Z.

The second redistribution structure 203 may be disposed on the upper surface of the molding member 390. According to embodiments, the second redistribution structure 203 may include a second redistribution insulation layer 210, a second redistribution pattern 230, and a heat conduction pattern 250. The second redistribution insulation layer 210 may extend in the first horizontal direction X and may overlap the first chip 300 in the vertical direction Z. The second redistribution pattern 230 may be formed in the second redistribution insulation layer 210 and may be formed not to overlap the heat dissipation chip 400 in the vertical direction Z. The heat conduction pattern 250 may be formed in a region which overlaps the heat dissipation chip 400 in the vertical direction Z. The heat conduction pattern 250 may be formed to overlap the first chip 300 in the vertical direction Z. The heat conduction pattern 250 may be formed between the first chip 300 and the heat dissipation chip 400. The heat conduction pattern 250 may be formed to penetrate through the second redistribution insulation layer 210 up to a lower surface of the heat dissipation chip 400 from an upper surface of the molding member 390. The heat conduction pattern 250 may not be electrically connected with the first chip 300. The heat conduction pattern 250 may penetrate through a plurality of second redistribution insulation layers 210 at a time, and thus, may be provided as a single body. Accordingly, a thickness of the heat conduction pattern 250 in the vertical direction Z may be substantially equal to a thickness of the second redistribution structure 203 in the vertical direction Z. According to embodiments, the heat conduction pattern 250 may have a shape which extends in the vertical direction Z. According to embodiments, the heat conduction pattern 250 may have a tapered shape where a horizontal width decreases as a level in the vertical direction Z decreases.

The heat dissipation chip 400 may be fixed to an upper surface of the second redistribution structure 203 through a TIM layer 430. The heat dissipation chip 400 may be disposed on the heat conduction pattern 250 and may physically contact the heat conduction pattern 250 and the TIM layer 430.

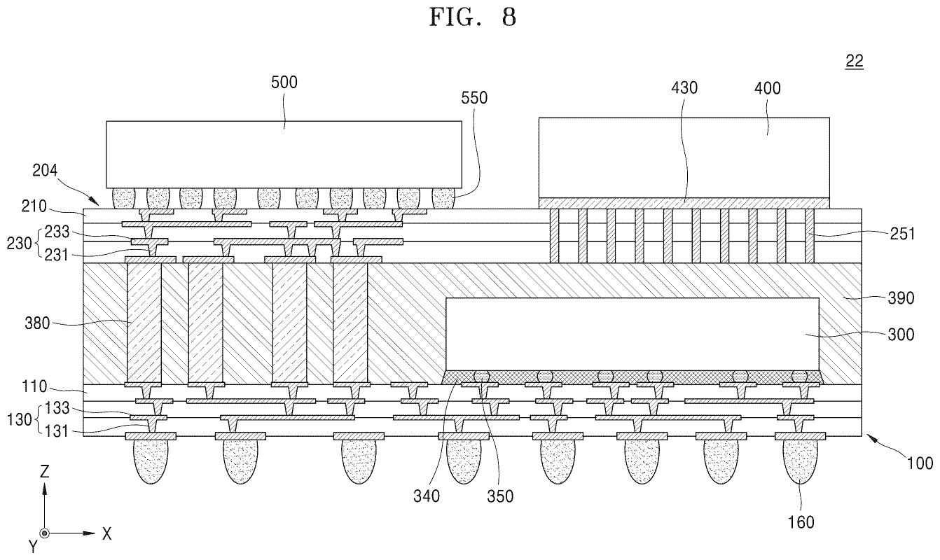

FIG. 8 is a cross-sectional view illustrating a semiconductor package 22 according to an embodiment. Hereinafter, descriptions of the semiconductor package 22 of FIG. 8 which are the same as or similar to the descriptions of the semiconductor package 21 described above with reference to FIG. 7 are omitted, and a difference therebetween will be mainly described.

Referring to FIG. 8, the semiconductor package 22 may include a first chip 300, a molding member 390, a conductive pillar 380, a second redistribution structure 204, a heat dissipation chip 400, and a second chip 500.

The second redistribution structure 204 may include a second redistribution insulation layer 210, a second redistribution pattern 230, and a heat conduction pattern 251. The heat conduction pattern 251 may be formed to penetrate through a plurality of second redistribution insulation layers 210. The heat conduction pattern 251 may be formed between the first chip 300 and the heat dissipation chip 401. The heat conduction pattern 251 may have a shape which extends in the vertical direction Z. According to embodiments, the heat conduction pattern 251 may have a shape where a horizontal width is constant, regardless of a level in the vertical direction Z.

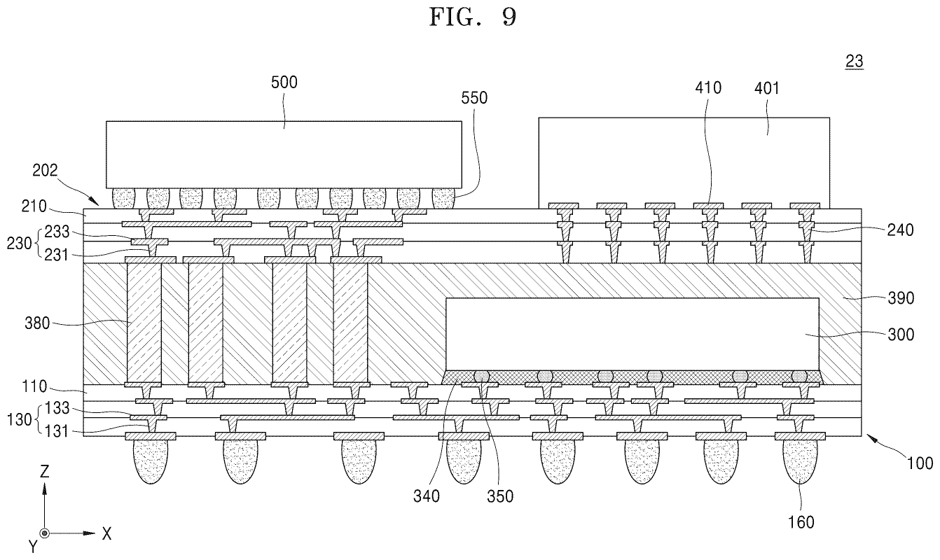

FIG. 9 is a cross-sectional view illustrating a semiconductor package 23 according to an embodiment. Hereinafter, descriptions of the semiconductor package 23 of FIG. 9 which are the same as or similar to the descriptions of the semiconductor package 20 described above with reference to FIG. 6 are omitted, and a difference therebetween will be mainly described.

Referring to FIG. 9, the semiconductor package 23 may include a first chip 300, a molding member 390, a conductive pillar 380, a second redistribution structure 202, a heat dissipation chip 401, and a second chip 500. The second redistribution structure 202 may include a second redistribution insulation layer 210, a second redistribution pattern 230, and a heat conduction pattern 240.

According to embodiments, the head dissipation chip 401 may include a heat dissipation chip pad 410 which is formed on a lower surface. The heat dissipation chip pad 410 may include plurality. According to embodiments, each of the plurality of heat dissipation chip pads 410 may be disposed to correspond to the heat conduction pattern 240 in a one-to-one relationship. For example, one heat conduction pattern 240 may contact one heat dissipation chip pad 410. The heat dissipation chip 401 may be bonded to the heat conduction pattern 240 by direct bonding between the heat dissipation chip pad 410 and the heat conduction pattern 240. However, embodiments are not limited thereto. Because the heat dissipation chip 401 is directly bonded to the heat conduction pattern 240, heat occurring in the first chip 300 may be more easily transferred to the heat dissipation chip 400.

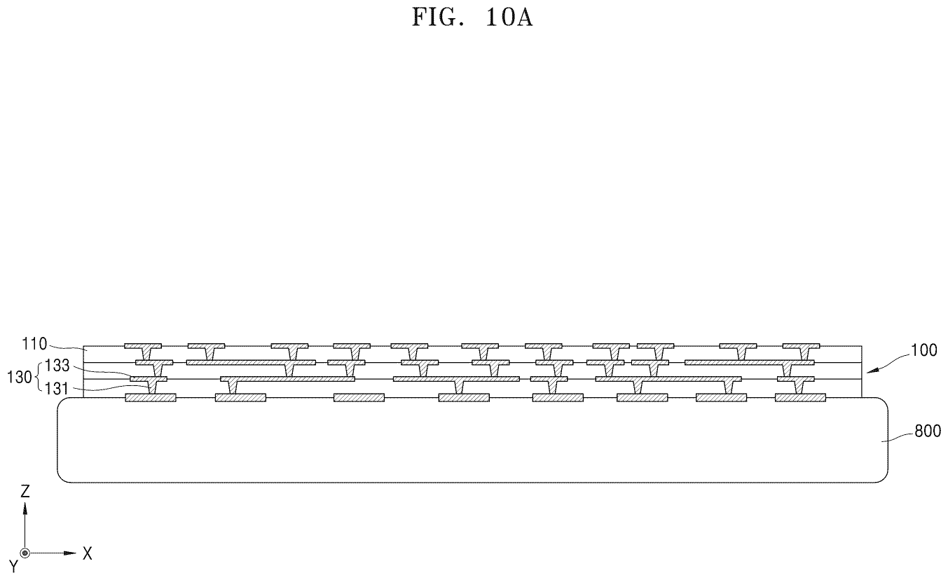

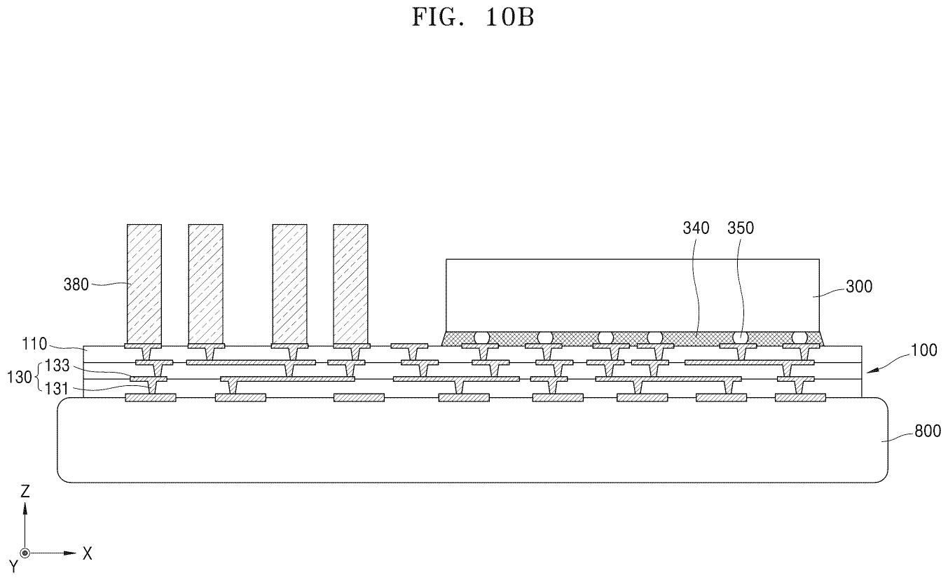

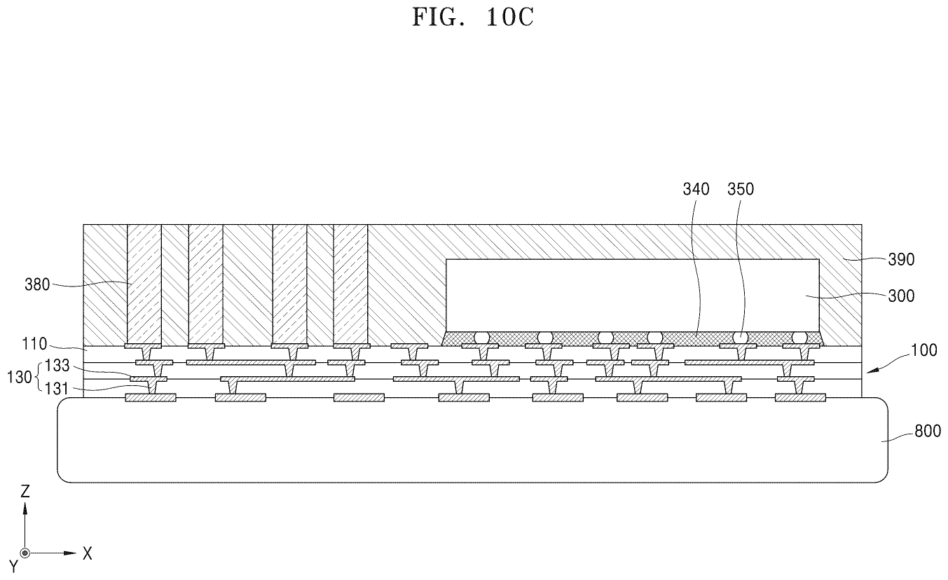

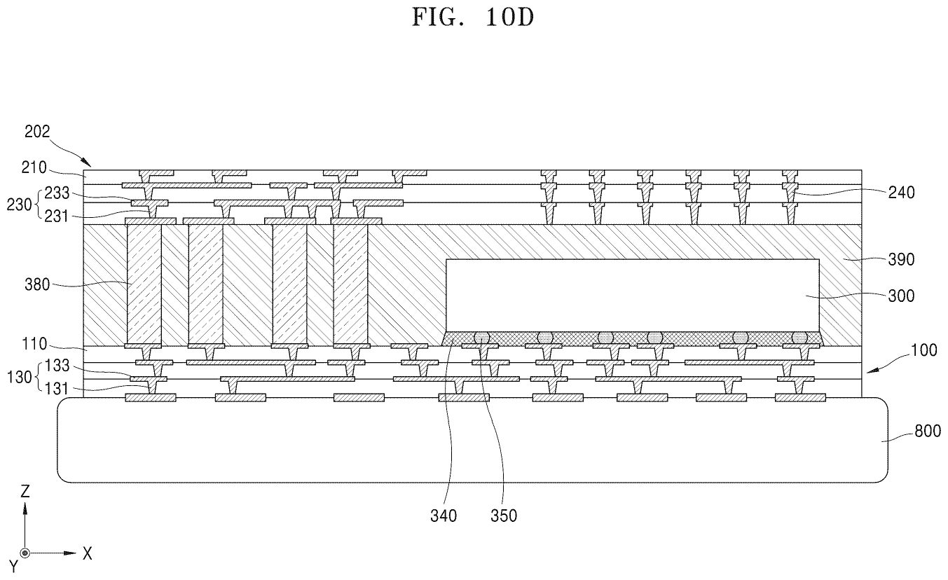

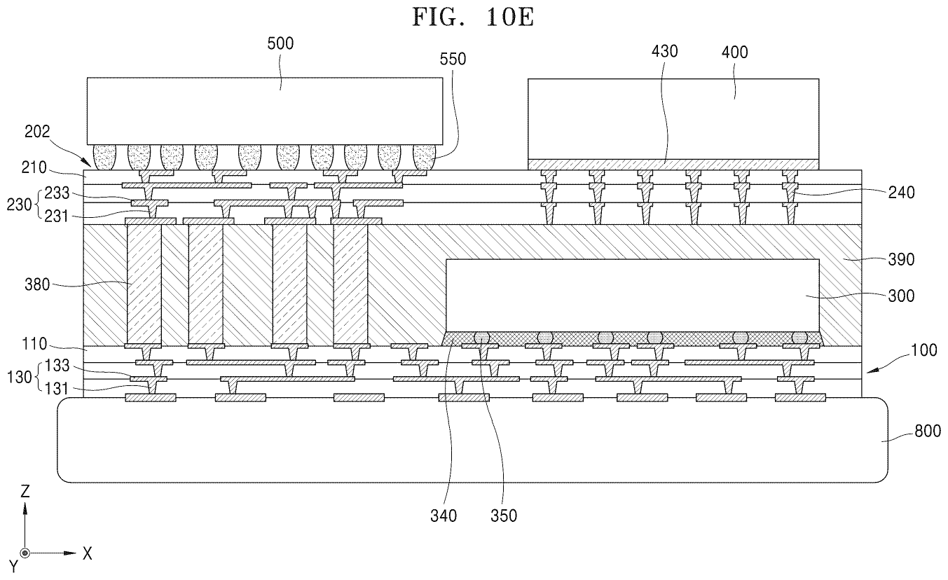

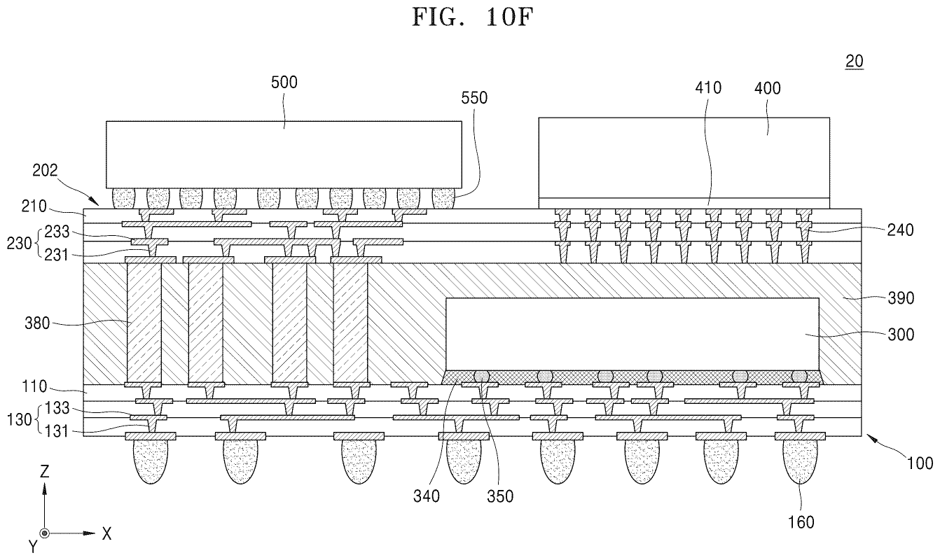

FIGS. 10A to 10F are cross-sectional views illustrating a method of manufacturing a semiconductor package, according to an embodiment. FIGS. 10A to 10C may be substantially the same as the descriptions of FIGS. 5A to 5C, and thus, detailed descriptions thereof are omitted.

Referring to FIG. 10D, a second redistribution structure 202 may be formed on an upper surface of a molding member 390. A second redistribution insulation layer 210 may be formed to overlap a first chip 300 in the vertical direction Z. According to embodiments, a heat conduction pattern 240 may be formed at a portion, overlapping the first chip 300 in the vertical direction Z, of the second redistribution insulation layer 210, and a second redistribution pattern 230 may be formed at a portion, which does not overlap the first chip 300 in the vertical direction Z, of the second redistribution insulation layer 210. The second redistribution pattern 230 may not contact the heat conduction pattern 240. The heat conduction pattern 240 may not be electrically connected with the second chip 500.

Referring to FIG. 10E, a second chip 500 and a heat dissipation chip 400 may be formed on a surface of the second redistribution structure 202. The second chip 500 may be formed in a region which overlaps the second redistribution pattern 230 in the vertical direction Z, and the head dissipation chip 400 may be formed in a region which overlaps the heat conduction pattern 240 in the vertical direction Z. The second chip 500 may be mounted on the second redistribution structure 202 as a flip chip type through a second bump 550, and the heat dissipation chip 400 may be fixed to the second redistribution structure 202 through a TIM layer 430.

Referring to FIG. 10F, a carrier substrate 800 may be removed, and an external connection terminal 160 may be formed under a first redistribution structure 100, thereby manufacturing the semiconductor package 20.

Hereinabove, example embodiments have been described in the drawings and the specification. Embodiments have been described by using the terms described herein, but this has been merely used for describing the present disclosure and has not been used for limiting a meaning or limiting the scope as defined in the following claims and their equivalents. Therefore, it may be understood by those of ordinary skill in the art that various modifications and other equivalent embodiments may be implemented from the embodiments. Accordingly, the spirit and scope may be defined based on the spirit and scope of the following claims and their equivalents.

While embodiments have been described with reference to the figures, it will be understood by those of ordinary skill in the art that various changes in form and details may be made therein without departing from the spirit and scope as defined by the following claims and their equivalents.

What is claimed is:

1. A semiconductor package, comprising:
a first redistribution structure;
a first chip on the first redistribution structure;
a molding member on the first redistribution structure and surrounding the first chip;
a conductive pillar penetrating through the molding member in a first direction;
a second redistribution structure on a first surface of the molding member;
a second chip on the second redistribution structure; and
a heat dissipation chip at least partially overlapping the first chip in the first direction,
wherein the second redistribution structure at least partially overlaps the heat dissipation chip in a second direction that intersects the first direction.

2. The semiconductor package of claim 1, wherein a level of a first surface of the heat dissipation chip in the first direction is equal to a level of a first surface of the second chip in the first direction.

3. The semiconductor package of claim 1, wherein the heat dissipation chip is in a cavity penetrating through the second redistribution structure in the first direction, and
wherein the second redistribution structure is at a side of the heat dissipation chip in the second direction.

4. The semiconductor package of claim 1, wherein a level in the first direction of a portion, overlapping the second redistribution structure, of a first surface of the molding member in the first direction is higher than a level in the first direction of a portion, which does not overlap the second redistribution structure, of the first surface of the molding member in the first direction.

5. The semiconductor package of claim 1, further comprising a thermal interfacial material (TIM) layer between the heat dissipation chip and the molding member.

6. The semiconductor package of claim 1, wherein the first chip is connected to a first redistribution pattern through a first bump between the first chip and the first redistribution structure.

7. The semiconductor package of claim 6, wherein the first chip comprises a first through via extending in the first direction, and
wherein a second through via penetrating through the molding member in the first direction from the first surface of the molding member to a first surface of the first chip is on a first surface of the first through via.

8. The semiconductor package of claim 7, wherein the second redistribution structure comprises a second redistribution pattern, and
wherein the second through via contacts the second redistribution pattern.

9. The semiconductor package of claim 1, wherein a heat dissipation chip pad is on a second surface of the heat dissipation chip, and an adhesive layer is between the heat dissipation chip and the molding member.

10. The semiconductor package of claim 1, wherein the heat dissipation structure comprises silicon and is spaced apart from the second redistribution structure in the second direction.

11. A semiconductor package comprising:
a first redistribution structure;
a first chip on the first redistribution structure;
a molding member on the first redistribution structure and surrounding the first chip;
a conductive pillar penetrating through the molding member in a first direction;
a second redistribution structure on a first surface of the molding member;
a second chip on the second redistribution structure; and
a heat dissipation chip on the second redistribution structure and spaced apart from the second chip in a second direction that intersects the first direction to at least partially overlap the first chip in the first direction,
wherein the second redistribution structure comprises a second redistribution insulation layer, a second redistribution pattern, and a heat conduction pattern,
wherein the second redistribution pattern electrically connects the second chip with the conductive pillar, and
wherein the heat conduction pattern penetrates through the second redistribution structure in the first direction from the first surface of the molding member to a second surface of the heat dissipation chip.

12. The semiconductor package of claim 11, wherein the heat conduction pattern is electrically disconnected to the first chip.

13. The semiconductor package of claim 11, wherein the second redistribution insulation layer comprises a plurality of second redistribution insulation layers stacked in the first direction, and
wherein the heat conduction pattern comprises a plurality of heat conduction patterns, each of the plurality of heat conduction patterns being included in the plurality of second redistribution insulation layers.

14. The semiconductor package of claim 11, wherein the heat conduction pattern penetrates through the second redistribution structure in the first direction from a first surface of the second redistribution structure to a second surface of the second redistribution structure, and
wherein a thickness of the heat conduction pattern in the first direction is equal to a thickness of the second redistribution structure in the first direction.

15. The semiconductor package of claim 14, wherein the heat conduction pattern has a tapered shape with a width in the second direction decreases as a level of the heat conduction patter in the first direction decreases.

16. The semiconductor package of claim 11, further comprising a thermal interfacial material (TIM) layer between the heat dissipation chip and the second redistribution structure.

17. The semiconductor package of claim 11, further comprising a heat dissipation chip pad on a second surface of the heat dissipation chip,
wherein the heat dissipation chip pad is connected to the heat conduction pattern.

18. A semiconductor package comprising:
a first redistribution structure;
a first chip on the first redistribution structure;
a molding member on the first redistribution structure and surrounding the first chip;
a conductive pillar arranged spaced apart from the first chip in a second direction to penetrate through the molding member in a first direction that intersects the second direction;
a second redistribution structure on a first surface of the molding member;
a second chip on the second redistribution structure;
a heat dissipation chip on the second redistribution structure and spaced apart from the second chip in the second direction to at least partially overlap the first chip in the first direction; and
a thermal interfacial material (TIM) layer between the heat dissipation chip and the second redistribution structure,
wherein the second redistribution structure comprises a second redistribution insulation layer, a second redistribution pattern, and a heat conduction pattern,
wherein the heat conduction pattern is electrically disconnected to the first chip,
wherein the second redistribution pattern electrically connects the second chip to the conductive pillar,
wherein the heat conduction pattern penetrates through the second redistribution structure in the first direction from the first surface of the molding member to a second surface of the heat dissipation chip, and
wherein the first chip comprises a logic chip, the second chip comprises a memory chip, and the heat dissipation chip comprises silicon.

19. The semiconductor package of claim 18, wherein the second redistribution insulation layer comprises a plurality of second redistribution insulation layers stacked in the first direction, and
wherein the heat conduction pattern comprises a plurality of heat conduction patterns, each of the plurality of heat conduction patterns being included in the plurality of second redistribution insulation layers.

20. The semiconductor package of claim 18, wherein the heat conduction pattern penetrates through the second redistribution structure in the first direction from a first surface of the second redistribution structure to a second surface of the second redistribution structure,
wherein a thickness of the heat conduction pattern in the first direction is equal to a thickness of the second redistribution structure in the first direction, and
wherein the heat conduction pattern has a tapered shape with a width in the second direction decreases as a level in the first direction of the heat conduction pattern in the first direction decreases.
